(19) United States
(12) Patent Application Publication
(10) Pub. No.: US 2025/0063683 A1
(43) Pub. Date: Feb. 20, 2025

(54) BRACKET STRUCTURE, BRACKET MODULE AND WALL MOUNT MODULE

(71) Applicant: Wistron NeWeb Corporation, Hsinchu (TW)

(72) Inventors: Yu-Shuo WU, Hsinchu (TW); Yu-Chi CHEN, Hsinchu (TW)

(21) Appl. No.: 18/624,217

(22) Filed: Apr. 2, 2024

(30) Foreign Application Priority Data
Aug. 15, 2023 (TW) 112130580

(51) Int. Cl. H05K 7/14

(52) U.S. Cl. CPC H05K 7/1489; H05K 7/1407

(57) ABSTRACT

A bracket structure, a bracket module, and a wall mount module are proposed. The bracket structure includes a board and two sideboards. The two sideboards are connected to two sides of the board respectively. A virtual connection line is extended between the two sideboards. A gap is between the virtual connection line and a first surface of the board. The two sideboards include a first sideboard and a second sideboard. The first sideboard includes an extension part, and a groove is formed between the extension part and the board. The second sideboard includes a fastening part. Thus, the bracket structure of the present disclosure can be applied to various types of wall mount supports.

### RELATED APPLICATIONS

This application claims the benefit of priority to Taiwan Patent Application No. 112130580, filed on Aug. 15, 2023. The entire content of the above identified application is incorporated herein by reference.

### BACKGROUND

### Technical Field

The present disclosure relates to a bracket structure, a bracket module, and a wall mount module, in particular to a bracket structure, a bracket module, and a wall mount module applicable to various types of mounting methods.

### Description of Related Art

Currently available electrical components such as switches and servers are mostly mounted on wall screws or DIN rails through brackets. However, for different types of wall mount supports such as wall screws and DIN rails, users need to purchase corresponding brackets for compatibility. This not only causes inconvenience for users but also requires manufacturers to design multiple brackets for different types of wall mount supports, resulting in significant production costs.

In view of this, the development of a bracket suitable for various forms of wall mount supports has become a crucial challenge faced by relevant industry players.

### SUMMARY

An object of the present disclosure is to provide a bracket structure, a bracket module, and a wall mount module that can adjust the method of connecting electrical components based on the types of wall mount supports. This not only eliminates user inconvenience but also results in cost savings for manufacturers in bracket development.

According to one embodiment of the structural configuration disclosed herein, a bracket module is provided. The bracket module includes a pending device and a bracket structure. The bracket structure is connected to the pending device. The bracket structure includes a board and two sideboards. The two sideboards are connected to two sides of the board respectively. A virtual connection line is extended between the two sideboards. A gap is between the virtual connection line and a first surface of the board.

According to another embodiment of the structural configuration disclosed herein, a bracket structure is provided. The bracket structure includes a board and two sideboards. The two sideboards are connected to two sides of the board respectively. A virtual connection line is extended between the two sideboards. A gap is between the virtual connection line and a first surface of the board. The two sideboards include a first sideboard and a second sideboard. The first sideboard includes an extension part. A groove is formed between the extension part and the board. The second sideboard includes a fastening part.

According to yet another embodiment of the structural configuration disclosed herein, a wall mount module is provided. The wall mount module includes a wall mount support and a bracket structure. The wall mount support is connected with a wall. The bracket structure is connected to the wall mount support, and is configured to be connected to a pending device. The bracket structure includes a board and two sideboards. The two sideboards are connected to two sides of the board respectively. A virtual connection line is extended between the two sideboards. A gap is between the virtual connection line and a first surface of the board.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1A is a perspective view of a wall mount module according to first embodiment of the present disclosure.

FIG. 1B is a cross-sectional view of the wall mount module as shown in FIG. 1A.

FIG. 1C is a perspective view of a bracket structure as shown in FIG. 1A according to the first embodiment of the present disclosure.

FIG. 1D is a cross-sectional view of the bracket structure as shown in FIG. 1C.

FIG. 1E is a perspective view of a wall mount module according to second embodiment of the present disclosure.

FIG. 1F is a cross-sectional view of the wall mount module as shown in FIG. 1E.

FIG. 2A is a perspective view of a bracket structure according to third embodiment of the present disclosure.

FIG. 2B is a cross-sectional view of the bracket structure as shown in FIG. 2A.

FIG. 2C is a cross-sectional view of a wall mount module according to third embodiment of the present disclosure.

FIG. 2D is a cross-sectional view of the wall mount module according to fourth embodiment of the present disclosure.

FIG. 3A is a perspective view of a bracket structure according to fifth embodiment of the present disclosure.

FIG. 3B is a cross-sectional view of the bracket structure as shown in FIG. 3A.

FIG. 3C is a cross-sectional view of a wall mount module according to the fifth embodiment of the present disclosure.

FIG. 3D is a cross-sectional view of a wall mount module according to sixth embodiment of the present disclosure.

FIG. 4A is a perspective view of a bracket structure according to seventh embodiment of the present disclosure.

FIG. 4B is a cross-sectional view of the bracket structure as shown in FIG. 4A.

FIG. 4C is a cross-sectional view of the wall mount module according to the seventh embodiment of the present disclosure.

FIG. 4D is a cross-sectional view of a wall mount module according to eighth embodiment of the present disclosure.

FIG. 5A is a perspective view of a bracket structure according to ninth embodiment of the present disclosure.

FIG. 5B is a cross-sectional view of the bracket structure as shown in FIG. 5A.

FIG. 5C is a cross-sectional view of the wall mount module according to the ninth embodiment of the present disclosure.

FIG. 5D is a cross-sectional view of a wall mount module according to tenth embodiment of the present disclosure.

FIG. 6A is a perspective view of a bracket structure according to eleventh embodiment of the present disclosure.

FIG. 6B is a cross-sectional view of the bracket structure as shown in FIG. 6A.

FIG. 6C is a cross-sectional view of the wall mount module according to the eleventh embodiment of the present disclosure.

FIG. 6D is a cross-sectional view of a wall mount module according to twelfth embodiment of the present disclosure.

### DETAILED DESCRIPTION

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

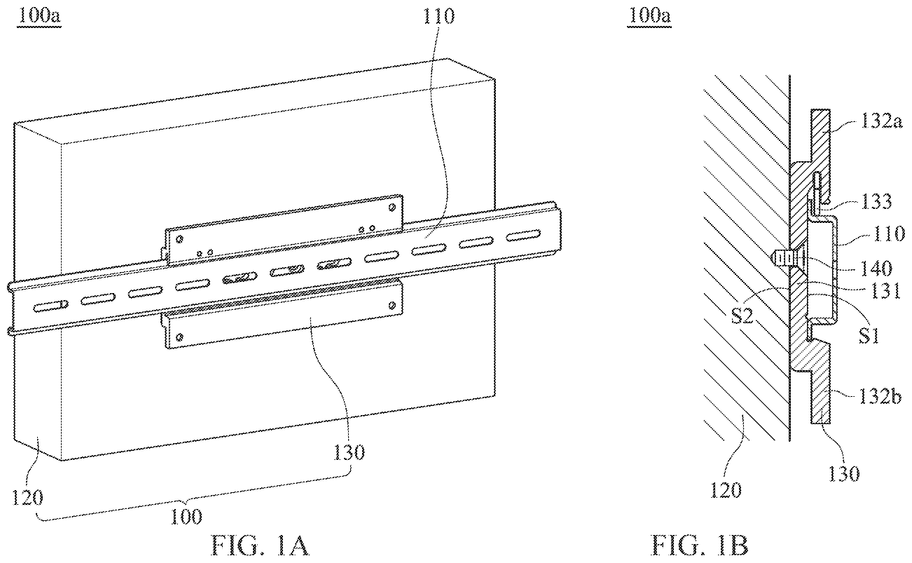

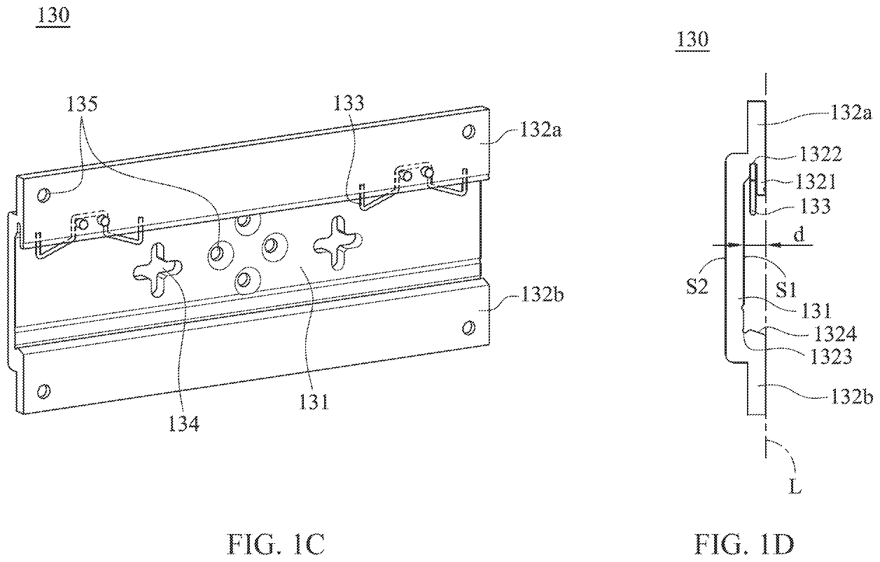

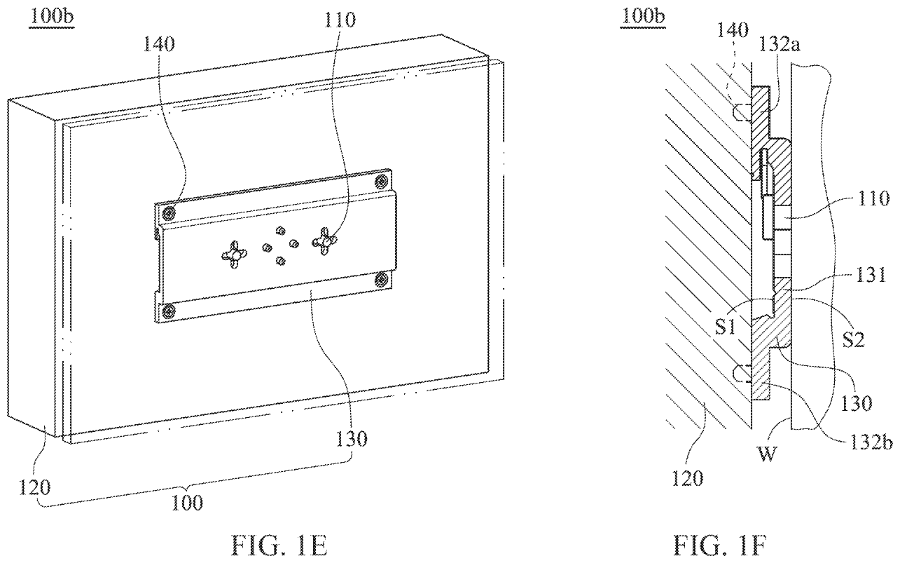

Refers to FIG. 1A, FIG. 1B, FIG. 1C, and FIG. 1D. FIG. 1A is a perspective view of a wall mount module 100a according to first embodiment of the present disclosure. FIG. 1B is a cross-sectional view of the wall mount module 100a as shown in FIG. 1A. FIG. 1C is a perspective view of a bracket structure 130 as shown in FIG. 1A according to the first embodiment of the present disclosure. FIG. 1D is a cross-sectional view of the bracket structure 130 as shown in FIG. 1C. The wall mount module 100a includes a wall mount support 110 and a bracket module 100. The bracket module 100 includes a pending device 120, a bracket structure 130, and a connection component 140. The wall mount support 110 is connected to a wall (not shown in the figure). The bracket structure 130 is connected to the wall mount support 110, and is connected to the pending device 120 through the connection component 140. In the first embodiment, the pending device 120 can be an electrical component such as a switch or a server. The connection component 140 can be a screw or a bolt, and the present disclosure is not limited thereto.

Refers to FIG. 1A to FIG. 1D. The bracket structure 130 includes a board 131, two sideboards (e.g., a first sideboard 132a and a second sideboard 132b as shown in the figure), an elastic element 133, a punch 134, and locking holes 135. The two sideboards are connected to two sides of the board 131 respectively. The elastic element 133 is disposed between the board 131 and one of the sideboards. The punch 134 is disposed on the board 131. The locking holes 135 are disposed on the board 131 and the two sideboards. In the first embodiment, the elastic element 133 can be a spring or a reed. The punch 134 can be a cross hole, and the present disclosure is not limited thereto.

Refers to FIG. 1D. The board 131 includes a first surface S1 and a second surface S2 that are oppositely arranged. A virtual connection line L is extended between the two sideboards. A gap d is between the virtual connection line L and the first surface S1 of the board 131. Specifically, the length of the first sideboard 132a along the virtual connection line L is the same as the length of the second sideboard 132b along the virtual connection line L. Both the lengths of the first sideboard 132a and the second sideboard 132b are smaller than the length of the board 131. The first sideboard 132a includes an extension part 1321. The extension part 1321 is extended toward the second sideboard 132b along the virtual connection line L. A groove 1322 is formed between the extension part 1321 and the first surface S1 of the board 131. The elastic element 133 is disposed in the groove 1322. The second sideboard 132b includes a fastening part 1323 and an inclined surface 1324. The inclined surface 1324 is connected to the fastening part 1323.

Refers to FIG. 1A to FIG. 1D. In the first embodiment, the wall mount support 110 of the wall mount module 100a is a DIN rail. The locking holes 135 on the board 131 are configured for the connection component 140 to pass through to connect the pending device 120 and the bracket structure 130 so as to connect the pending device 120 to the second surface S2 of the board 131. The fastening part 1323 is configured to be embedded by the wall mount support 110. The inclined surface 1324 is configured to guide the wall mount support 110 to be embedded in the fastening part 1323. The elastic element 133 is configured to push the wall mount support 110 and to position the wall mount support 110 at the fastening part 1323 and connect it to the first surface S1. Detailed steps for connecting the bracket structure 130 and the wall mount support 110 are as follows. First, hang the first sideboard 132a of the bracket structure 130 to the top of the wall mount support 110 and contact the elastic element 133. Then push the second sideboard 132b toward the wall mount support 110, and release the bracket structure 130 after the board 131 is in contact with the wall mount support 110. That is, the wall mount support 110 can be positioned at the fastening part 1323 to connect the bracket structure 130 and the wall mount support 110.

Refers to FIG. 1C, FIG. 1D, FIG. 1E, and FIG. 1F together. FIG. 1E is a perspective view of a wall mount module 100b according to second embodiment of the present disclosure. FIG. 1F is a cross-sectional view of the wall mount module 100b as shown in FIG. 1E. In the second embodiment, the wall mount module 100b also includes the wall mount support 110 and the pending device 120 as shown in FIG. 1A and FIG. 1B. Differences between the wall mount module 100b of the second embodiment and the wall mount module 100a of the first embodiment are the types of the wall mount support 110 and connection relationships of the bracket structure 130 with respect to the pending device 120 and the wall mount support 110 respectively. Specifically, the wall mount support 110 of the wall mount module 100b is a bolt and is connected to a wall W. The locking holes 135 on the first sideboard 132a and the second sideboard 132b are configured for the connection component 140 to pass through to connect the pending device 120 and the bracket structure 130 so as to connect the pending device 120 to the first sideboard 132a and the second sideboard 132b. The punch 134 is configured for the wall mount support 110 to be embedded in from the second surface S2 so as to connect the wall mount support 110 to the bracket structure 130.

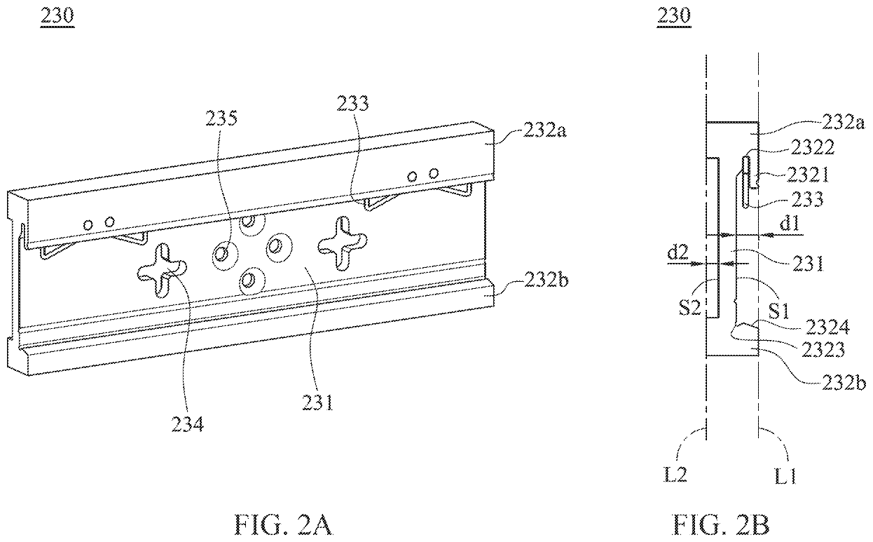

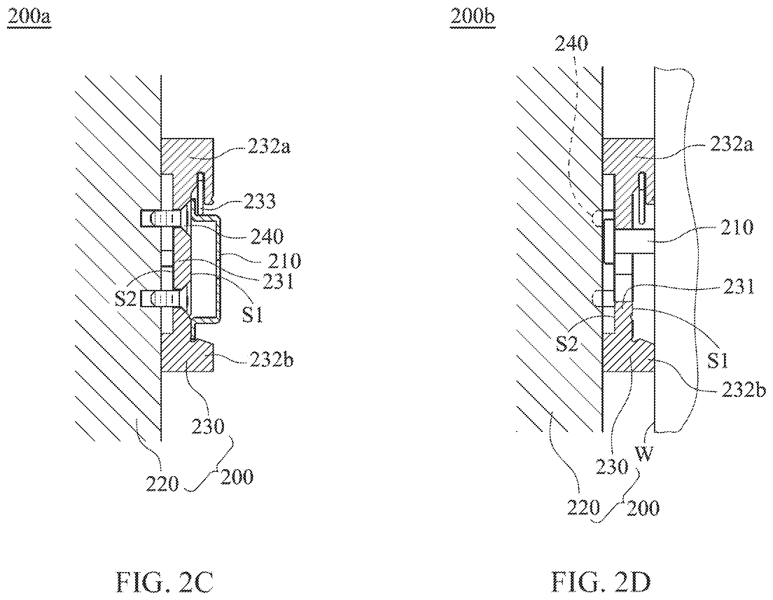

Refers to FIG. 2A, FIG. 2B, and FIG. 2C. FIG. 2A is a perspective view of a bracket structure 230 according to third embodiment of the present disclosure. FIG. 2B is a cross-sectional view of the bracket structure 230 as shown in FIG. 2A. FIG. 2C is a cross-sectional view of a wall mount module 200a according to third embodiment of the present disclosure. The wall mount module 200a includes a wall mount support 210 and a bracket module 200. The bracket module 200 includes a pending device 220, a bracket structure 230, and a connection component 240. The wall mount support 210 is connected to a wall (not shown in the figure). The bracket structure 230 is connected to the wall mount support 210, and is connected to the pending device 220 through the connection component 240. In the third embodiment, the wall mount support 210, the pending device 220, and the connection component 240 are the same as the wall mount support 110, the pending device 120, and the connection component 140 in the first embodiment, respectively, and will not be repeated herein.

Refers to FIG. 2A and FIG. 2B. The bracket structure 230 includes a board 231, two sideboards (e.g., a first sideboard 232a and a second sideboard 232b as shown in figures), an elastic element 233, a punch 234, and locking holes 235. The two sideboards are connected to two sides of the board 231 respectively. The elastic element 233 is disposed between the board 231 and one of the sideboards. The punch 234 and the locking holes 235 are disposed on the board 231. In the third embodiment, the elastic element 233 and the punch 234 are the same as the elastic element 133 and the punch 134 in the first embodiment, and will not be repeated herein.

Refers to FIG. 2B. The board 231 includes a first surface S1 and a second surface S2 that are oppositely arranged. A virtual connection line L1 is extended between the two sideboards. A gap d1 is between the virtual connection line L1 and the first surface S1 of the board 231. Another virtual connection line L2 is extended between the two sideboards. Another gap d2 is between the another virtual connection line L2 and the second surface S2 of the board 231. Specifically, the length of the first sideboard 232a along the virtual connection line L1 is slightly greater than the length of the second sideboard 232b along the virtual connection line L1. Both the lengths of the first sideboard 232a and the second sideboard 232b are smaller than the length of the board 231. The first sideboard 232a includes an extension part 2321. The extension part 2321 is extended toward the second sideboard 232b along the virtual connection line L1. A groove 2322 is formed between the extension part 2321 and the first surface S1 of the board 231. The elastic element 233 is disposed in the groove 2322. The second sideboard 232b includes a fastening part 2323 and an inclined surface 2324. The inclined surface 2324 is connected to the fastening part 2323.

Refers to FIG. 2A, FIG. 2B, and FIG. 2C. In the third embodiment, the wall mount support 210 of the wall mount module 200a is a DIN rail. The locking holes 235 are configured for the connection component 240 to pass through to connect the pending device 220 and the bracket structure 230 so as to connect the pending device 220 to the second surface S2 of the board 231. In the third embodiment, the functions of the fastening part 2323 and the inclined surface 2324, and the steps of connecting the bracket structure 230 and the wall mount support 210 are the same as that disclosed in the first embodiment, and will not be repeated herein.

Refers to FIG. 2A, FIG. 2B, FIG. 2C, and FIG. 2D together. FIG. 2D is a cross-sectional view of the wall mount module 200b according to fourth embodiment of the present disclosure. In the fourth embodiment, the wall mount module 200b also includes the wall mount support 210 and the pending device 220 as shown in FIG. 2C. Differences of the wall mount module 200b in the fourth embodiment and the wall mount module 200a in the third embodiment are the types of the wall mount support 210, and the connection relations of the bracket structure 230 and the and the wall mount support 210. Specifically, the wall mount support 210 of the wall mount module 200b is a bolt and is connected to the wall W. The locking holes 235 are configured for the connection component 240 to pass through to connect the pending device 220 and the bracket structure 230 so as to connect the pending device 220 to the second surface S2 of the board 231. The punch 234 is configured for the wall mount support 210 to be embedded in from the first surface S1 so as to connect the wall mount support 210 to the bracket structure 230.

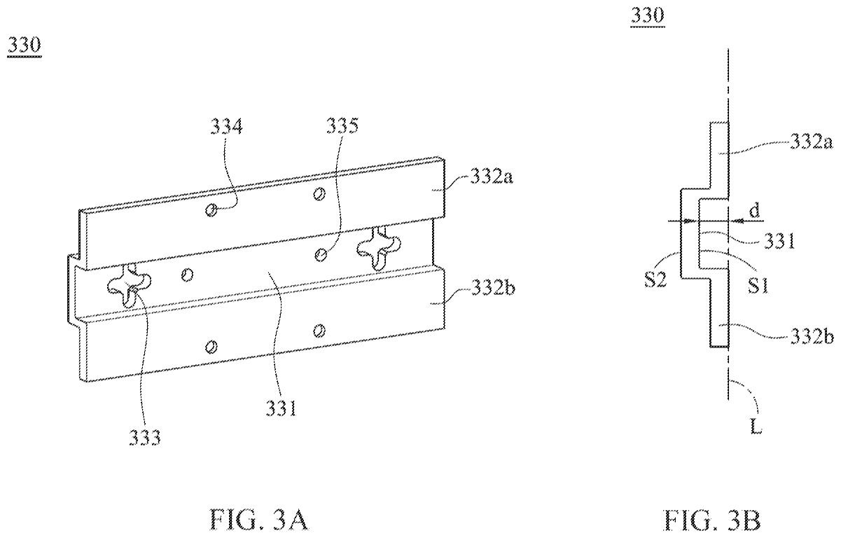

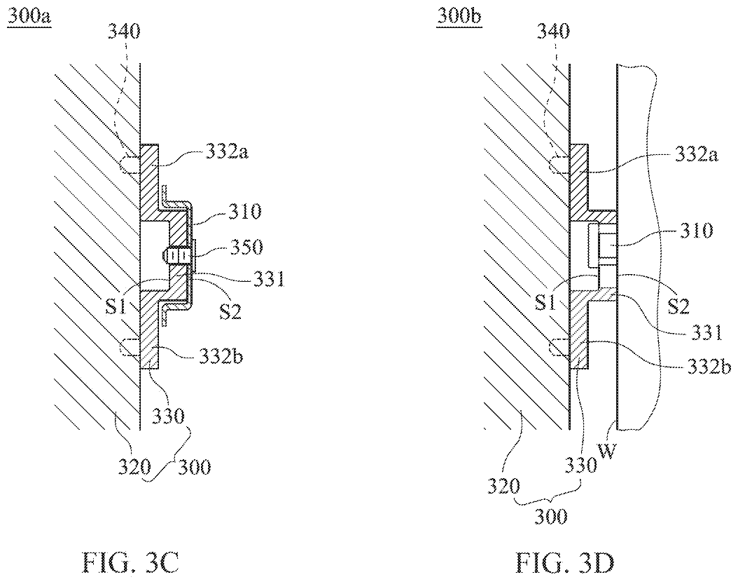

Refers to FIG. 3A, FIG. 3B, and FIG. 3C. FIG. 3A is a perspective view of a bracket structure 330 according to fifth embodiment of the present disclosure. FIG. 3B is a cross-sectional view of the bracket structure 330 as shown in FIG. 3A. FIG. 3C is a cross-sectional view of a wall mount module 300a according to the fifth embodiment of the present disclosure. The wall mount module 300a includes a wall mount support 310 and a bracket module 300. The bracket module 300 includes a pending device 320, a bracket structure 330, a connection component 340, and a combination element 350. The wall mount support 310 is connected to a wall (not shown in the figure). The bracket structure 330 is connected to the wall mount support 310 through the combination element 350, and is connected to the pending device 320 through the connection component 340. In the fifth embodiment, the combination element 350 can be a screw, and the present disclosure is not limited thereto. The wall mount support 310, the pending device 320, and the connection component 340 are the same as the wall mount support 110, the pending device 120, and the connection component 140 in the first embodiment, respectively, and will not be repeated herein.

Refers to FIG. 3A and FIG. 3B. The bracket structure 330 includes a board 331, two sideboards (e.g., a first sideboard 332a and a second sideboard 332b as shown in the figure), a punch 333, locking holes 334, and a combination hole 335. The two sideboards are connected to two sides of the board 331 respectively. The punch 333 and the combination hole 335 are disposed on the board 331. The locking holes 334 are disposed on the two sideboards. In the fifth embodiment, the punch 333 is the same as the punch 134 in the first embodiment, and will not be repeated herein.

Refers to FIG. 3B. The board 331 includes a first surface S1 and a second surface S2 that are oppositely arranged. A virtual connection line L is extended between the two sideboards. A gap d is between the virtual connection line L and the first surface S1 of the board 331. Specifically, the length of the first sideboard 332a along the virtual connection line L is the same as the length of the second sideboard 332b along the virtual connection line L. Both the lengths of the first sideboard 332a and the second sideboard 332b are smaller than the length of the board 331.

Refers to FIG. 3A, FIG. 3B, AND FIG. 3C. In the fifth embodiment, the wall mount support 310 of the wall mount module 300a is a DIN rail. The locking holes 334 are configured for the connection component 340 to pass through to connect the pending device 320 and the bracket structure 330 so as to connect the pending device 320 to the first sideboard 332a and the second sideboard 332b. The combination hole 335 is configured for the combination element 350 to pass through the wall mount support 310 and is embedded from the second surface S2, so that the wall mount support 310 is attached to the second surface S2 and is connected to the bracket structure 330.

Refers to FIG. 3A, FIG. 3B, FIG. 3C, and FIG. 3D. FIG. 3D is a cross-sectional view of a wall mount module 300b according to sixth embodiment of the present disclosure. In the sixth embodiment, the wall mount module 300b also includes the wall mount support 310 and the pending device 320 as shown in FIG. 3C. Differences between the wall mount module 300b in the sixth embodiment and the wall mount module 300a in the fifth embodiment are the types of the wall mount support 310, and connection relations of the bracket structure 330 and the wall mount support 310. Specifically, the wall mount support 310 of the wall mount module 300b is a screw and is connected to the wall W. The locking holes 334 are configured for the connection component 340 to pass through to connect the pending device 320 and the bracket structure 330 so as to connect the pending device 320 to the first sideboard 332a and the second sideboard 332b. The punch 333 is configured for the wall mount support 310 to be embedded from the second surface S2 so as to connect the wall mount support 310 to the bracket structure 330.

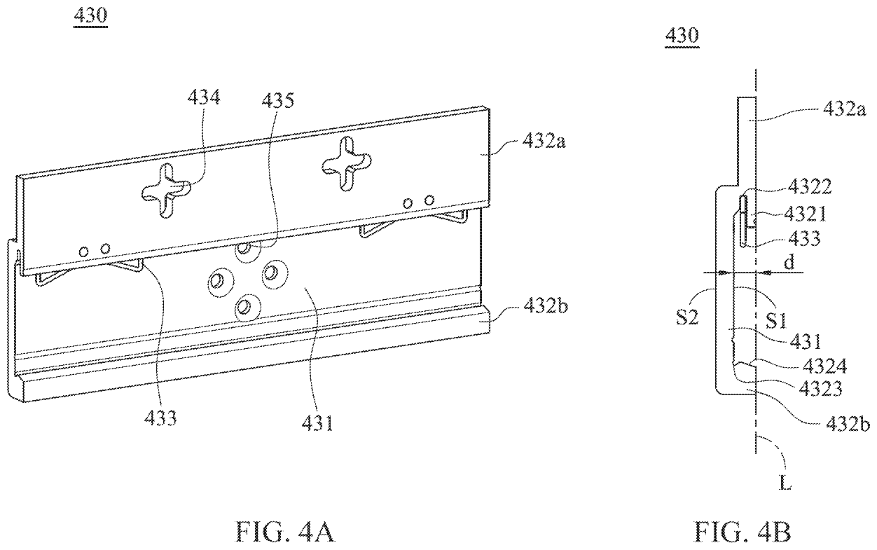

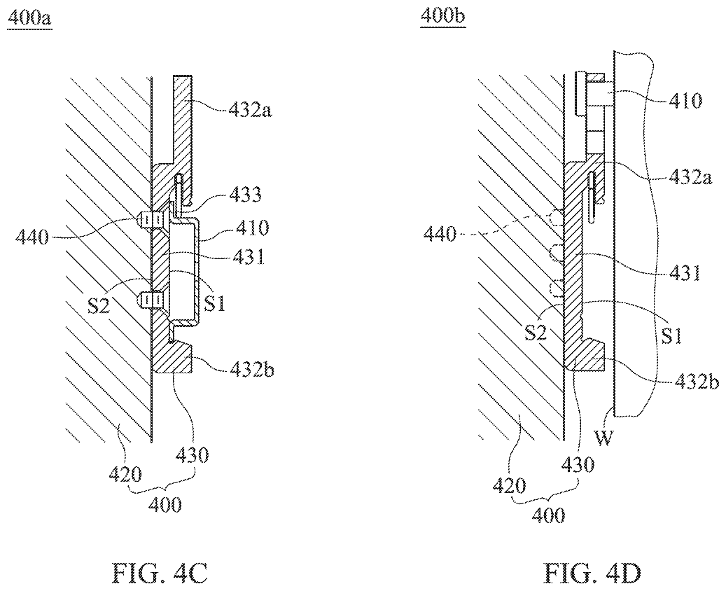

Refers to FIG. 4A, FIG. 4B, and FIG. 4C. FIG. 4A is a perspective view of a bracket structure 430 according to seventh embodiment of the present disclosure. FIG. 4B is a cross-sectional view of the bracket structure 430 as shown in FIG. 4A. FIG. 4C is a cross-sectional view of the wall mount module 400a according to the seventh embodiment of the present disclosure. The wall mount module 400a includes a wall mount support 410 and a bracket module 400. The bracket module 400 includes a pending device 420, a bracket structure 430, and a connection component 440. The wall mount support 410 is connected to a wall (not shown in the figure). The bracket structure 430 is connected to the wall mount support 410, and is connected to the pending device 420 through the connection component 440. In the seventh embodiment, the wall mount support 410, the pending device 420, and the connection component 440 are the same as the wall mount support 110, the pending device 120, and the connection component 140 in the first embodiment, respectively, and will not be repeated herein.

Refers to FIG. 4A and FIG. 4B. The bracket structure 430 includes a board 431, two sideboards (e.g., a first sideboard 432a and a second sideboard 432b as shown in the Figure), an elastic element 433, a punch 434, and locking holes 435. Two sideboards are connected to two sides of the board 431 respectively. The elastic element 433 is disposed between the board 431 and one of the sideboards. The punch 434 is disposed on one of the sideboards. The locking holes 435 are disposed on the board 431. In the seventh embodiment, the elastic element 433 and the punch 434 are the same as the elastic element 133 and the punch 134 in the first embodiment respectively, and will not be repeated herein.

Refers to FIG. 4B. The board 431 includes a first surface S1 and a second surface S2 that are oppositely arranged. A virtual connection line L is extended between the two sideboards. A gap d is between the virtual connection line L and the first surface S1 of the board 431. Specifically, the length of the first sideboard 432a along the virtual connection line L is greater than the length of the second sideboard 432b along the virtual connection line L. Both the lengths of the first sideboard 432a and the second sideboard 432b are smaller than the length of the board 431. The first sideboard 432a includes an extension part 4321. The extension part 4321 is extended toward the second sideboard 432b along the virtual connection line L. A groove 4322 is formed between the extension part 4321 and the first surface S1 of the board 431. The elastic element 433 is disposed in the groove 4322. The second sideboard 432b includes a fastening part 4323 and an inclined surface 4324. The inclined surface 4324 is connected to the fastening part 4323.

Refers to FIG. 4A, FIG. 4B, and FIG. 4C. In the seventh embodiment, the wall mount support 410 of the wall mount module 400a is a DIN rail. The locking holes 435 are configured for the connection component 440 to pass through to connect the pending device 420 and the bracket structure 430 so as to connect the pending device 420 to the second surface S2 of the board 431. In the seventh embodiment, the functions of the fastening part 4323 and the inclined surface 4324, and the steps of connecting the bracket structure 430 and the wall mount support 410 are the same as that disclosed in the first embodiment, and will not be repeated herein.

Refers to FIG. 4A, FIG. 4B, FIG. 4C, and FIG. 4D. FIG. 4D is a cross-sectional view of a wall mount module 400b according to eighth embodiment of the present disclosure. In the eighth embodiment, the wall mount module 400b also includes the wall mount support 410 and the pending device 420 as shown in FIG. 4C. Differences between the wall mount module 400b of the eighth embodiment and the wall mount module 400a of the seventh embodiment are the types of the wall mount support 410, and connection relations of the bracket structure 430 and the wall mount support 410. Specifically, the wall mount support 410 of the wall mount module 400b is a bolt and is connected to the wall W. The locking holes 435 are configured for the connection component 440 to pass through to connect the pending device 420 and the bracket structure 430 so as to connect the pending device 420 to the second surface S2 of the board 431. The punch 434 is configured for the wall mount support 410 to be embedded from the first sideboard 432a so as to connect the wall mount support 410 to the bracket structure 430.

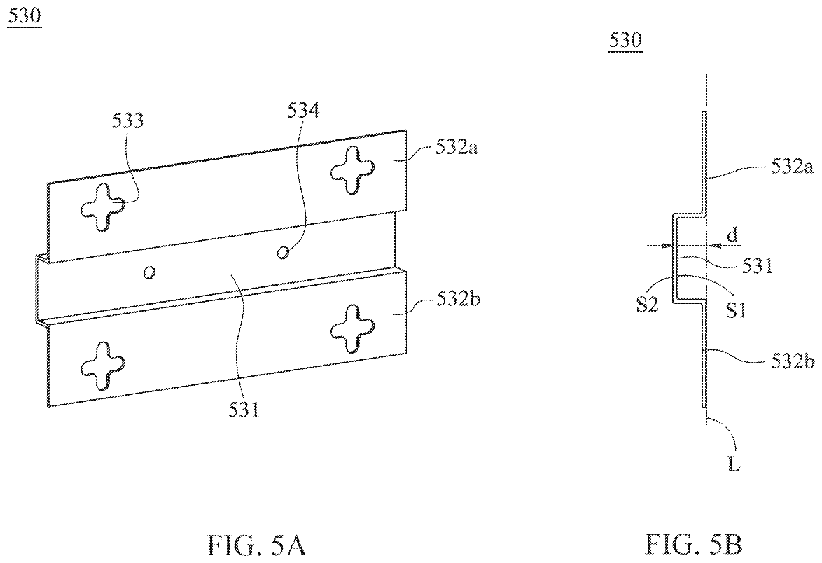

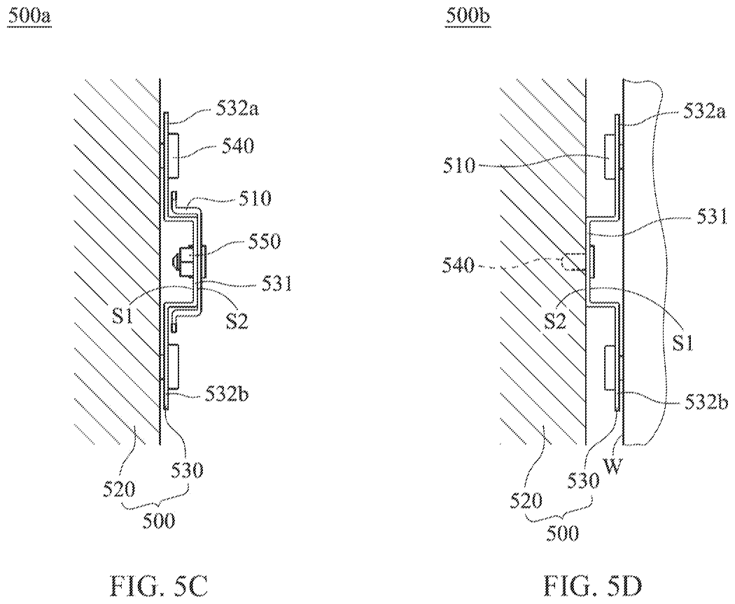

Refers to FIG. 5A, FIG. 5B, and FIG. 5C. FIG. 5A is a perspective view of a bracket structure 530 according to ninth embodiment of the present disclosure. FIG. 5B is a cross-sectional view of the bracket structure 530 as shown in FIG. 5A. FIG. 5C is a cross-sectional view of the wall mount module 500a according to the ninth embodiment of the present disclosure. The wall mount module 500a includes a wall mount support 510 and a bracket module 500. The bracket module 500 includes a pending device 520, a bracket structure 530, a connection component 540, and a combination element 550. The wall mount support 510 is connected to a wall (not shown in the figure). The bracket structure 530 is connected to the wall mount support 510 through the combination element 550, and is connected to the pending device 520 through the connection component 540. In the ninth embodiment, the wall mount support 510, the pending device 520, and the connection component 540 are the same as the wall mount support 110, the pending device 120, and the connection component 140 in the first embodiment respectively. The combination element 550 is the same as the combination element 350 in the fifth embodiment, and will not be repeated herein.

Refers to FIG. 5A and FIG. 5B. The bracket structure 530 includes a board 531, two sideboards (e.g., a first sideboard 532a and a second sideboard 532b as shown in the figure), a punch 533, and locking holes 534. Two sideboards are connected to two sides of the board 531 respectively. The punch 533 is disposed on the board 531. The locking holes 534 are disposed on the two sideboards. In the ninth embodiment, the punch 533 is the same as the punch 134 in the first embodiment, and will not be repeated herein.

Refers to FIG. 5B. The board 531 includes a first surface S1 and a second surface S2 that are oppositely arranged. A virtual connection line L is extended between the two sideboards. A gap d is between the virtual connection line L and the first surface S1 of the board 531. Specifically, the length of the first sideboard 532a along the virtual connection line L is the same as the length of the second sideboard 532b along the virtual connection line L. Both the lengths of the first sideboard 532a and the second sideboard 532b are greater than the length of the board 531.

Refers to FIG. 5A, FIG. 5B, and FIG. 5C. In the ninth embodiment, the wall mount support 510 of the wall mount module 500a is a DIN rail. The punch 533 allows the connection component 540 to pass through to connect the pending device 520 to the bracket structure 530 so as to connect the pending device 520 to the first sideboard 532a and the second sideboard 532b. The locking holes 534 are configured for the combination element 550 to pass through the wall mount support 510 and is embedded from the second surface S2, so that the wall mount support 510 is attached to the second surface S2 and is connected to the bracket structure 530.

Refers to FIG. 5A, FIG. 5B, FIG. 50, and FIG. 5D. FIG. 5D is a cross-sectional view of a wall mount module 500b according to tenth embodiment of the present disclosure. In the tenth embodiment, the wall mount module 500b also includes the wall mount support 510 and the pending device 520 as shown in FIG. 5C. Differences between the wall mount module 500b in the tenth embodiment and the wall mount module 500a in the ninth embodiment are the types of the wall mount support 510 and connection relations of the bracket structure 530 with respect to the pending device 520 and the wall mount support 510, respectively. Specifically, the wall mount support 510 of the wall mount module 500b is a bolt and is connected to the wall W. The locking holes 534 are configured for the connection component 540 to pass through to connect the pending device 520 and the bracket structure 530 so as to connect the pending device 520 to the second surface S2 of the board 531. The punch 533 is configured for the wall mount support 510 to be embedded in so as to connect the wall mount support 510 to the bracket structure 530.

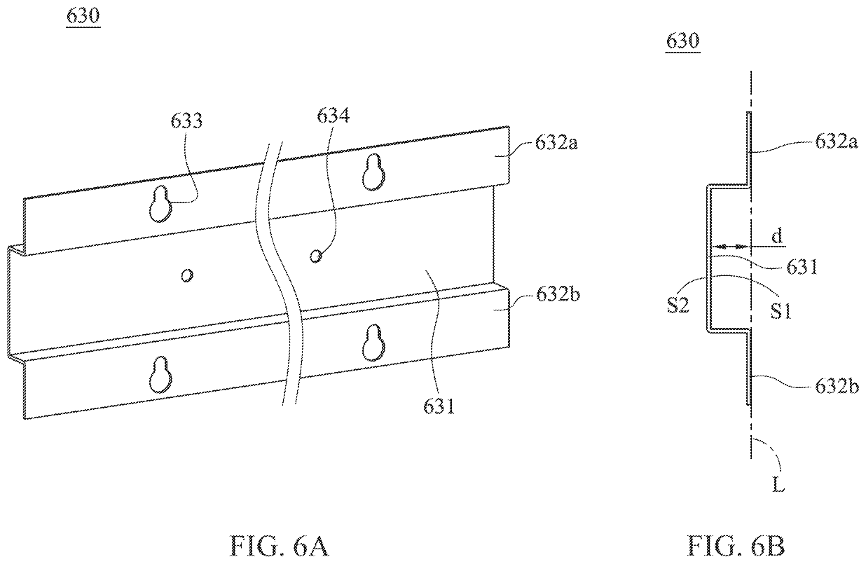

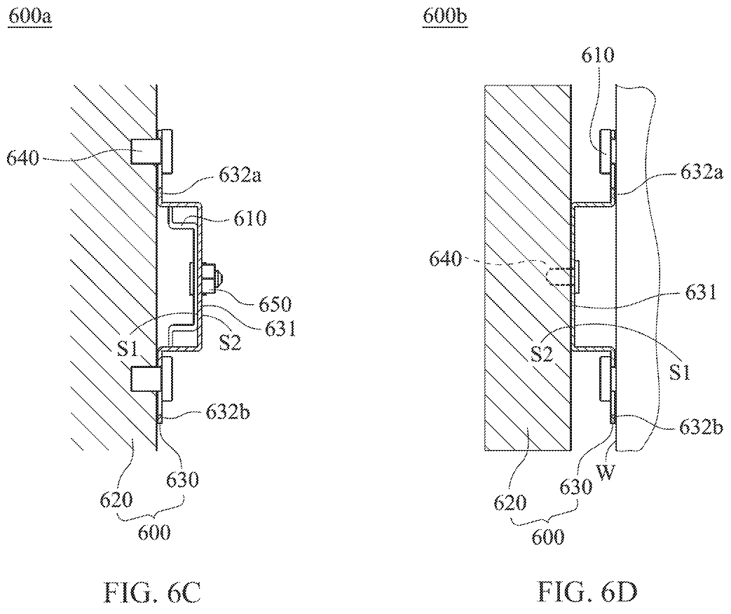

Refers to FIG. 6A, FIG. 6B, and FIG. 6C. FIG. 6A is a perspective view of a bracket structure 630 according to eleventh embodiment of the present disclosure. FIG. 6B is a cross-sectional view of the bracket structure 630 as shown in FIG. 6A. FIG. 6C is a cross-sectional view of the wall mount module 600a according to the eleventh embodiment of the present disclosure. The wall mount module 600a includes a wall mount support 610 and a bracket module 600. The bracket module 600 includes a pending device 620, a bracket structure 630, a connection component 640, and a combination element 650. The wall mount support 610 is connected to a wall (not shown in the figure). The bracket structure 630 is connected to the wall mount support 610 through the combination element 650, and is connected to the pending device 620 through the connection component 640. In the eleventh embodiment, the wall mount support 610, the pending device 620, and the connection component 640 are the same as the wall mount support 110, the pending device 120, and the connection component 140 in the first embodiment, respectively. The combination element 650 is the same as the combination element 350 in the fifth embodiment, and will not be repeated herein.

Refers to FIG. 6A and FIG. 6B. The bracket structure 630 includes a board 631, two sideboards (e.g., a first sideboard 632a and a second sideboard 632b as shown in the figure), a punch 633, and locking holes 634. The two sideboards are connected to two sides of the board 631 respectively. The punch 633 is disposed on the two sideboards. The locking holes 634 are disposed on the board 631.

Refers to FIG. 6B. The board 631 includes a first surface S1 and a second surface S2 that are oppositely arranged. A virtual connection line L is extended between the two sideboards. A gap d is between the virtual connection line L and the first surface S1 of the board 631. Specifically, the length of the first sideboard 632a and the length of the second sideboard 632b are the same. Both the lengths of the first sideboard 632a and the second sideboard 632b are smaller than the length of the board 631.

Refers to FIG. 6A, FIG. 6B, and FIG. 6C. In the eleventh embodiment, the wall mount support 610 of the wall mount module 600a is a DIN rail. The punch 633 is configured for the connection component 640 to pass through to connect the pending device 620 and the bracket structure 630 so as to connect the pending device 620 to the first sideboard 632a and the second sideboard 632b. The locking holes 634 are configured for the combination element 650 to pass through the wall mount support 610 and is embedded in from the second surface S2, so that the wall mount support 610 is attached to the first surface S1 and is connected to the bracket structure 630.

Refers to FIG. 6A, FIG. 6B, FIG. 6C, and FIG. 6D. FIG. 6D is a cross-sectional view of a wall mount module 600b according to twelfth embodiment of the present disclosure. In the twelfth embodiment, the wall mount module 600b also includes the wall mount support 610 and the pending device 620 as shown in FIG. 6C. Differences between the wall mount module 600b in the twelfth embodiment and the wall mount module 600a in the eleventh embodiment are the types of the wall mount support 610 and connection relations of the bracket structure 630 with respect to the pending device 620 and the wall mount support 610, respectively. Specifically, the wall mount support 610 of the wall mount module 600b is a bolt and is connected to the wall W. The locking holes 634 are configured for the connection component 640 to pass through to connect the pending device 620 and the bracket structure 630 so as to connect the pending device 620 to the second surface S2 of the board 631. The punch 633 is configured for the wall mount support 610 to be embedded in so as to connect the wall mount support 610 to the bracket structure 630.

Therefore, the bracket structures 130, 230, 330, 430, 530, 630 can provide corresponding connection means according to the types of the wall mount supports 110, 210, 310, 410, 510, 610, thereby achieving the effect of reduce parts development and production costs.

From the above embodiments, the present disclosure has the following advantages: Firstly, through the design of the bracket structure, a single bracket structure can be used for different types of wall mount supports, enhancing user convenience and expanding ways of using. At the same time, it also helps save production costs for relevant manufacturers in bracket development. Secondly, the connection method between the bracket structure, the wall mount support, and the pending device is simple and quick, making it easy for users to assemble or replace.

The foregoing description of the disclosure has been presented only for the purposes of illustration and description option of the exemplary embodiments and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A bracket module, comprising:
a pending device; and
a bracket structure connected to the pending device, the bracket structure comprising:
a board; and
two sideboards connected to two sides of the board respectively, a virtual connection line being extended between the two sideboards, and a gap being between the virtual connection line and a first surface of the board.

2. The bracket module according to claim 1, wherein the two sideboards comprise:
a first sideboard comprising an extension part, a groove being formed between the extension part and the board; and
a second sideboard comprising a fastening part, the fastening part being configured to be embedded by a wall mount support, and the wall mount support being configured to be connected to a wall.

3. The bracket module according to claim 2, wherein
the bracket structure further comprises an elastic element disposed in the groove and configured to push the wall mount support and position the wall mount support at the fastening part; and
the second sideboard further comprises an inclined surface, the inclined surface is connected to the fastening part.

4. The bracket module according to claim 3, wherein
when the pending device is connected to a second surface of the board, the bracket structure is configured to connect the first surface of the board to the wall mount support.

5. The bracket module according to claim 1, wherein
when the pending device is connected to the two sideboards, the bracket structure is configured to connect a second surface of the board to a wall mount support, and the wall mount support is configured to be connected to a wall.

6. The bracket module according to claim 1, wherein
another virtual connection line is extended between the two sideboards, and another gap is between the another virtual connection line and a second surface of the board; and
when the pending device is connected to the second surface of the board, the bracket structure is configured to connect the first surface of the board to a wall mount support, and the wall mount support is configured to be connected to a wall.

7. The bracket module according to claim 1, wherein
when the pending device is connected to a second surface of the board, the bracket structure is configured to connect at least one of the two sideboards to a wall mount support, and the wall mount support is configured to be connected to a wall.

8. The bracket module according to claim 1, further comprising a connection component configured to be connected with the pending device and the bracket structure, wherein the board comprises a plurality of locking holes disposed on the board and the two sideboards, and the locking holes are configured for the connection component to pass through to connect the pending device and the bracket structure.

9. A bracket structure, comprising:
a board; and
two sideboards connected to two sides of the board respectively, a virtual connection line being extended between the two sideboards, and a gap being between the virtual connection line and a first surface of the board, the two sideboards comprising:
a first sideboard comprising an extension part, a groove being formed between the extension part and the board; and
a second sideboard comprising a fastening part.

10. The bracket structure according to claim 9, wherein
the bracket structure further comprises an elastic element disposed in the groove and configured to push a wall mount support connected to a wall; and
the second sideboard further comprises an inclined surface, the inclined surface is connected to the fastening part, the fastening part is configured to be embedded by the wall mount support, and the elastic element is configured to position the wall mount support at the fastening part.

11. The bracket structure according to claim 10, wherein the bracket structure is configured to connect the first surface of the board to the wall mount support.

12. The bracket structure according to claim 9, wherein at least one of the two sideboards is configured to be connected with a wall mount support, the wall mount support is configured to be connected with a wall.

13. The bracket structure according to claim 9, further comprising:
a punch disposed on the board and at least one of the two sideboards, the punch being configured to be embedded by a wall mount support connected to a wall, whereby the wall mount support being connected to the bracket structure.

14. A wall mount module, comprising:
a wall mount support configured to be connected with a wall; and
a bracket structure connected to the wall mount support and configured to be connected to a pending device, the bracket structure comprising:
a board; and
two sideboards connected to two sides of the board respectively, a virtual connection line being extended between the two sideboards, and a gap being between the virtual connection line and a first surface of the board.

15. The wall mount module according to claim 14, wherein the two sideboards comprise:
a first sideboard comprising an extension part, a groove being formed between the extension part and the board; and
a second sideboard comprising a fastening part, the fastening part being configured to be embedded by a wall mount support.

16. The wall mount module according to claim 15, wherein
the bracket structure further comprises an elastic element disposed in the groove and configured to push the wall mount support and position the wall mount support at the fastening part; and
the second sideboard further comprises an inclined surface, the inclined surface is connected to the fastening part.

17. The wall mount module according to claim 16, wherein
when the pending device is connected to a second surface of the board, the bracket structure is configured to connect the first surface of the board to the wall mount support.

18. The wall mount module according to claim 14, wherein
when the pending device is connected to the two sideboards, the bracket structure is configured to connect a second surface of the board to a wall mount support, and the wall mount support is configured to be connected to a wall.

19. The wall mount module according to claim 14, wherein
another virtual connection line is extended between the two sideboards, and another gap is between the another virtual connection line and a second surface of the board; and
when the pending device is connected to the second surface of the board, the bracket structure is configured to connect the first surface of the board to a wall mount support, and the wall mount support is configured to be connected to a wall.

20. The wall mount module according to claim 14, wherein
when the pending device is connected to a second surface of the board, the bracket structure is configured to connect at least one of the two sideboards to a wall mount support, and the wall mount support is configured to be connected to a wall.
